(19) United States
(12) Patent Application Publication
(10) Pub. No.: US 2005/0120953 A1
(43) Pub. Date: Jun. 9, 2005

(54) Method of and apparatus for supplying a dynamic protective layer to a mirror

(75) Inventors: Vadim Yevgenyevich Banine, Helmond (NL); Levinus Pieter Bakker, Helmond (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 10/957,753

(22) Filed: Oct. 5, 2004

(30) Foreign Application Priority Data
Oct. 6, 2003 (EP) 03078140.5

(51) Int. Cl. C23C 16/00

(52) U.S. Cl. 118/715; 427/248.1; 427/9

(57) ABSTRACT

A method of supplying a dynamic protective layer to a mirror in a lithographic apparatus to protect the mirror from etching by ions is disclosed. The method includes supplying a gaseous matter to a chamber that contains the mirror, monitoring reflectivity of the mirror, and controlling the thickness of the protective layer by controlling a potential of the surface of the mirror, based on the monitored reflectivity of the mirror.

### CROSS-REFERENCE TO RELATED APPLICATIONS

This application claims the benefit of priority from European Patent Application No. 3078140.5, filed Oct. 6, 2003, the entire content of which is incorporated herein by reference.

### FIELD

The present invention relates to a method of supplying a dynamic protective layer to at least one mirror to protect the at least one mirror from etching by ions. The invention also relates to a device manufacturing method, an apparatus for supplying a dynamic protective layer to a mirror, and a lithographic projection apparatus.

### BACKGROUND

The term “patterning device” as here employed should be broadly interpreted as referring to a device that can be used to endow an incoming radiation beam with a patterned cross-section, corresponding to a pattern that is to be created in a target portion of the substrate; the term “light valve” can also be used in this context. Generally, the pattern will correspond to a particular functional layer in a device being created in the target portion, such as an integrated circuit or other device (see below).

Examples of such patterning devices include a mask. The concept of a mask is well known in lithography, and it includes mask types such as binary, alternating phase-shift, and attenuated phase-shift, as well as various hybrid mask types. Placement of such a mask in the radiation beam causes selective transmission (in the case of a transmissive mask) or reflection (in the case of a reflective mask) of the radiation impinging on the mask, according to the pattern on the mask. In the case of a mask, the support structure will generally be a mask table, which ensures that the mask can be held at a desired position in the incoming radiation beam, and that it can be moved relative to the beam if so desired.

Another example of such patterning devices include a programmable mirror array. One example of such a device is a matrix-addressable surface having a viscoelastic control layer and a reflective surface. The basic principle behind such an apparatus is that, for example, addressed areas of the reflective surface reflect incident light as diffracted light, whereas unaddressed areas reflect incident light as undiffracted light. Using an appropriate filter, the undiffracted light can be filtered out of the reflected beam, leaving only the diffracted light behind; in this manner, the beam becomes patterned according to the addressing pattern of the matrix-addressable surface. An alternative embodiment of a programmable mirror array employs a matrix arrangement of tiny mirrors, each of which can be individually tilted about an axis by applying a suitable localized electric field, or by employing a piezoelectric actuation device. Once again, the mirrors are matrix-addressable, such that addressed mirrors will reflect an incoming radiation beam in a different direction to unaddressed mirrors; in this manner, the reflected beam is patterned according to the addressing pattern of the matrix-addressable mirrors. The required matrix addressing can be performed using suitable electronic devices. In both of the situations described hereabove, the patterning device can include one or more programmable mirror arrays. More information on mirror arrays as here referred to can be gleaned, for example, from U.S. Pat No. 5,296,891 and U.S. Pat. No. 5,523,193, and PCT patent applications WO 98/38597 and WO 98/33096, which are incorporated herein by reference. In the case of a programmable mirror array, the support structure may be embodied as a frame or table, for example, which may be fixed or movable as required.

A further example of such patterning devices includes a programmable LCD array. An example of such a construction is given in U.S. Pat. No. 5,229,872, which is incorporated herein by reference. As above, the support structure in this case may be embodied as a frame or table, for example, which may be fixed or movable as required.

For purposes of simplicity, the rest of this text may, at certain locations, specifically direct itself to examples involving a mask and mask table; however, the general principles discussed in such instances should be seen in the broader context of the patterning device as hereabove set forth.

Lithographic projection apparatus can be used, for example, in the manufacture of integrated circuits (ICs). In such a case, the patterning device may generate a circuit pattern corresponding to an individual layer of the IC, and this pattern can be imaged onto a target portion (e.g. including one or more dies) on a substrate (silicon wafer) that has been coated with a layer of radiation-sensitive material (resist). In general, a single wafer will contain a whole network of adjacent target portions that are successively irradiated via the projection system, one at a time. In current apparatus, employing patterning by a mask on a mask table, a distinction can be made between two different types of machine. In one type of lithographic projection apparatus, each target portion is irradiated by exposing the entire mask pattern onto the target portion in one go; such an apparatus is commonly referred to as a wafer stepper or step-and-repeat apparatus. In an alternative apparatus—commonly referred to as a step-and-scan apparatus—each target portion is irradiated by progressively scanning the mask pattern under the projection beam in a given reference direction (the “scanning” direction) while synchronously scanning the substrate table parallel or anti-parallel to this direction; since, in general, the projection system will have a magnification factor M (generally <1), the speed V at which the substrate table is scanned will be a factor M times that at which the mask table is scanned. More information with regard to lithographic devices as here described can be gleaned, for example, from U.S. Pat. No. 6,046,792, incorporated herein by reference.

In a manufacturing process using a lithographic projection apparatus, a pattern (e.g. in a mask) is imaged onto a substrate that is at least partially covered by a layer of radiation-sensitive material (resist). Prior to this imaging step, the substrate may undergo various procedures, such as priming, resist coating and a soft bake. After exposure, the substrate may be subjected to other procedures, such as a post-exposure bake (PEB), development, a hard bake and measurement/inspection of the imaged features. This array of procedures is used as a basis to pattern an individual layer of a device, e.g. an IC. Such a patterned layer may then undergo various processes such as etching, ion-implantation (doping), metallization, oxidation, chemo-mechanical polishing, etc., all intended to finish off an individual layer. If several layers are required, then the whole procedure, or a variant thereof, will have to be repeated for each new layer. Eventually, an array of devices will be present on the substrate (wafer). These devices are then separated from one another by a technique such as dicing or sawing, whence the individual devices can be mounted on a carrier, connected to pins, etc. Further information regarding such processes can be obtained, for example, from the book “Microchip Fabrication: A Practical Guide to Semiconductor Processing”, Third Edition, by Peter van Zant, McGraw Hill Publishing Co., 1997, ISBN 0-07-067250-4, incorporated herein by reference.

For the sake of simplicity, the projection system may hereinafter be referred to as the “lens”; however, this term should be broadly interpreted as encompassing various types of projection systems, including refractive optics, reflective optics, and catadioptric systems, for example. The radiation system may also include components operating according to any of these design types for directing, shaping or controlling the projection beam of radiation, and such components may also be referred to below, collectively or singularly, as a “lens”. Further, the lithographic apparatus may be of a type having two or more substrate tables (and/or two or more mask tables). In such “multiple stage” devices the additional tables may be used in parallel, or preparatory steps may be carried out on one or more tables while one or more other tables are being used for exposures. Dual stage lithographic apparatus are described, for example, in U.S. Pat. No. 5,969,441 and WO 98/40791, both incorporated herein by reference.

In the case of this invention, the projection system will generally consist of an array of mirrors, and the mask will be reflective. The radiation in this case is preferably electromagnetic radiation in the extreme ultraviolet (EUV) range. Typically, the radiation has a wavelength below 50 nm, but preferably below 15 nm, for example, 13.7 or 11 nm. The source of EUV radiation is typically a plasma source, for example, a laser-produced plasma or a discharge source. The laser-produced plasma source may include water droplets, xenon, tin or a solid target that is irradiated by a laser to generate EUV radiation.

A common feature of any plasma source is the inherent production of fast ions and atoms, which are expelled from the plasma in all directions. These particles can be damaging to the collector and condenser mirrors, which are generally multilayer mirrors with fragile surfaces. This surface is gradually degraded due to the impact, or sputtering, of the particles expelled from the plasma and the lifetime of the mirrors is thus decreased. The surface of the mirror is further degraded by oxidation.

A measure that has previously been used and that does address the problem of damage to the mirrors, is to reduce the impact of the particle flux on the mirrors using a background gas of helium to impede the particles by collisions. However, this type of technique cannot reduce the sputtering rate to an acceptable level, while keeping the background pressure of, for example, helium low enough to ensure sufficient transparency to the radiation beam.

EP 1 186 957 A2 describes a method and apparatus for solving this problem by providing a gas supply device for supplying a gaseous hydrocarbon to a space containing a mirror (i.e. collector) and a reflectivity sensor that measures the sensitivity of the mirror. Further on, the pressure is measured by a pressure sensor. The introduction of hydrocarbon molecules in the chamber containing mirrors will lead to a hydrocarbon protective layer forming on the surface of the mirrors. This protective layer protects the mirror from chemical attack, such as oxidation and sputtering, but also decreases the reflectivity of the mirror.

The protective layer is gradually destroyed by sputtering and once it is has been eroded, damage to the mirror surface will occur. Therefore, it is advantageous to apply a protective layer that is not too thin. Secondly, if the protective layer is too thick, the reflectivity of the mirror is decreased to an unacceptable level, and the efficiency of the projection apparatus is reduced.

The invention described in EP 1 186 957 A2 solves this problem by creating a dynamic protective layer. The growing speed of the protective layer may be regulated by varying the gas pressure of the hydrocarbon. If the protective layer becomes too thick, the pressure is decreased and if the protective layer becomes to thin, the pressure is increased. By balancing the growth and the decline of the protective layer, a desired thickness may be maintained. Information about the thickness of the protective layer may be deduced from the reflectivity sensor.

It will be understood that at least the collector, i.e. the mirror that first receives the light and fast ions coming from the plasma source, will need to be protected using such a dynamic protective layer. The following mirrors are typically not subjected to these fast ions coming from the plasma source.

However, it has been discovered that the EUV radiation induces a plasma that includes positive ions and electrons in the chamber containing the mirrors. Both the ions and electrons may be absorbed by the surface of the mirror, but because the electrons are quicker than the positive ions, an electric field will arise in the vicinity of the mirror surface, typically over a distance corresponding to the length, which may be defined as the maximum distance in which concentrations of electrons and ions differ sensibly, thereby causing a local violation of the electrical quasi-neutrality. This phenomena is known to a person skilled in art.

As a result of this electric field, the ions will be accelerated in the direction of the mirror surface, causing etching or sputtering, degenerating the mirror surface. This effect is called plasma-induced etching. Plasma-induced etching occurs not only at the condenser mirrors, but also at the further mirrors.

It will be understood that the method of establishing a dynamic protective layer as described with reference to EP 1 186 957 is not applicable for the further mirrors, since, there, no fast ions are coming from the source. Further on, increasing the pressure will not only result in a thicker protective layer, but will also increase the plasma-induced etching. Also, because different mirrors are not subjected to the same sputtering conditions, a separate gas supply and gas chamber would have to be provided for each mirror, which is not practical.

### SUMMARY

Therefore, it is an aspect of the present invention to provide an alternative apparatus and method to protect the mirrors of the projection apparatus against plasma-induced etching and oxidation.

This may be achieved according to a method of supplying a dynamic protective layer to at least one mirror to protect the at least one mirror from etching by ions. The method includes supplying a gaseous matter to a chamber containing the at least one mirror, and monitoring reflectivity of the mirror. The thickness of the protective layer is controlled by controlling a potential of the surface of the mirror, based on the monitored reflectivity of the mirror. By controlling the potential of the surface of the mirror, the etching process of the mirror surface may be controlled. Because etching is caused by positive ions that are attracted to the surface of the mirror, adjusting the potential thereof controls the impact velocity of the atoms, and thus, the effectiveness of the etching.

The use of such a dynamic protective layer prevents mirror etching due to plasma-induced etching. By controlling the amount of growth and etching of the protective layer, the thickness of the protective layer can be controlled. This makes it possible to create a protective layer that has a certain desired thickness that protects the mirror from etching and does not reduce the reflectivity of the mirror too much. The protective layer further effectively protects the mirror against oxidation.

According to an embodiment of the invention, the gas is a gaseous hydrocarbon (HₓC_{y}), such as acetic anhydride, n-amyl alcohol, amyl benzoate, diethylene glycol ethyl ether, acrylic acid, adipic acid, 2-tert-butyl-4-ethylphenol. These gases are well suited to form a protective layer.

According to an embodiment of the invention, the at least one mirror is used to image a mask to a substrate. The invention may advantageously be used in a lithographic projection apparatus. Such an lithographic projection apparatus images a projection beam from a patterning device, such as a mask, to a substrate. Since the imaged pattern is usually very fine, the optics used in such a lithographic projection apparatus need to be protected from any damaging processes. Even a relatively small defect on the mirror surface may cause a defect in the produced substrate.

According to an embodiment of the invention, the at least one mirror is used to project an EUV radiation beam. The invention may be used in applications using EUV radiation. It has been discovered that EUV radiation may generate a plasma in front of a mirror. As discussed above, such a plasma will result in an electric field in the vicinity of the mirror, causing positive ions to etch the surface of the mirror. EUV applications are particular sensitive to defects on the mirror, since EUV radiation is usually used to project relatively very fine patterns from a mask to a substrate. Also, reflecting EUV radiation is difficult anyway.

According to an embodiment of the invention, the chamber has a background pressure that is monitored. This provides the ability to control the amount of gas in the chamber, and thus the growing speed of the protective layer, in a more accurate way.

According to a further aspect of the invention, the invention relates to a device manufacturing method that includes providing a substrate that is at least partially covered by a layer of radiation-sensitive material; providing a projection beam of radiation using a radiation system; using a patterning device to endow the projection beam with a pattern in its cross-section; projecting the patterned beam of radiation onto a target portion of the layer of radiation-sensitive material, and supplying a dynamic protective layer to at least one mirror to protect the at least one mirror from etching by ions, as described above.

According to a further aspect of the invention, the invention relates to an apparatus for supplying a dynamic protective layer to at least one mirror to protect the at least one mirror from etching by ions. The apparatus includes a chamber with the at least one mirror, an inlet for supplying a gaseous matter to the chamber containing the at least one mirror and a device for monitoring reflectivity of the mirror, and a controllable voltage source for applying a potential to the surface of the mirror in order to control the thickness of the protective layer in dependence on the reflectivity of the mirror. The apparatus as here described is arranged to supply a protective layer to the surface of the mirror by enabling a gaseous matter to enter the chamber. The gaseous matter will precipitate on the mirror surface, thereby forming a protective layer. The etching process, dominated by positive ions, may be controlled by controlling the potential of the mirror surface by controlling the controllable voltage source. By doing that, a dynamic protective layer is established, of which the thickness may easily be controlled.

According to an embodiment of the invention, the controllable voltage source is at one end connected to the at least one mirror, and at another end connected to an electrode facing the mirror. Such an apparatus may generate a reliable way of adjusting the potential of the reflective surface of the mirror. The electrode may have all kinds of shaped, such as a shape that resembles the shape and dimensions of the mirror. Alternatively, the electrode could also be a ring-shaped wire, a straight wire, or a point source, or any other suitable shape.

According to an embodiment of the invention, the controllable voltage source is at one end connected to the at least one mirror and at another end connected to ground. This is an easy and cost effective way of applying a potential to the surface.

According to an embodiment of the invention, the apparatus includes a monitor for monitoring a background pressure in the chamber containing the at least one mirror. This provides the ability to control the amount of gas in the chamber, and thus the growing speed of the protective layer, in a more accurate way.

According to a further aspect of the invention, the invention relates to a lithographic projection apparatus that includes a radiation system for providing a projection beam of radiation, and a support structure for supporting patterning device. The patterning device serves to pattern the projection beam according to a desired pattern. The apparatus also includes a substrate table for holding a substrate, a projection system for projecting the patterned beam onto a target portion of the substrate, and an apparatus for supplying a dynamic protective layer to at least one mirror to protect the at least one mirror from etching by ions. The apparatus that supplies the dynamic protective layer includes a chamber with the at least one mirror, an inlet for supplying a gaseous matter to the chamber containing the at least one mirror and a device for monitoring reflectivity of the mirror, and a controllable voltage source for applying a potential to the surface of the mirror in order to control the thickness of the protective layer in dependence on the reflectivity of the mirror.

Although specific reference may be made in this text to the use of the apparatus according to the invention in the manufacture of ICs, it should be explicitly understood that such an apparatus has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as being replaced by the more general terms “mask”, “substrate” and “target portion”, respectively.

In the present document, the terms “radiation” and “beam” are used to encompass all types of electromagnetic radiation, including ultraviolet (UV) radiation (e.g. with a wavelength of 365, 248, 193, 157 or 126 nm) and extreme ultra-violet (EUV) radiation (e.g. having a wavelength in the range 5-20 nm), as well as particle beams, such as ion beams or electron beams.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic projection apparatus according to an embodiment of the invention;

FIG. 2 depicts a mirror in a low pressure environment subjected to EUV radiation;

FIG. 3 depicts a mirror according to an embodiment of the present invention;

FIG. 4 depicts a chamber containing mirrors according to an embodiment of the present invention; and

FIG. 5 depicts a chamber containing mirrors according to an embodiment of the present invention.

### DETAILED DESCRIPTION

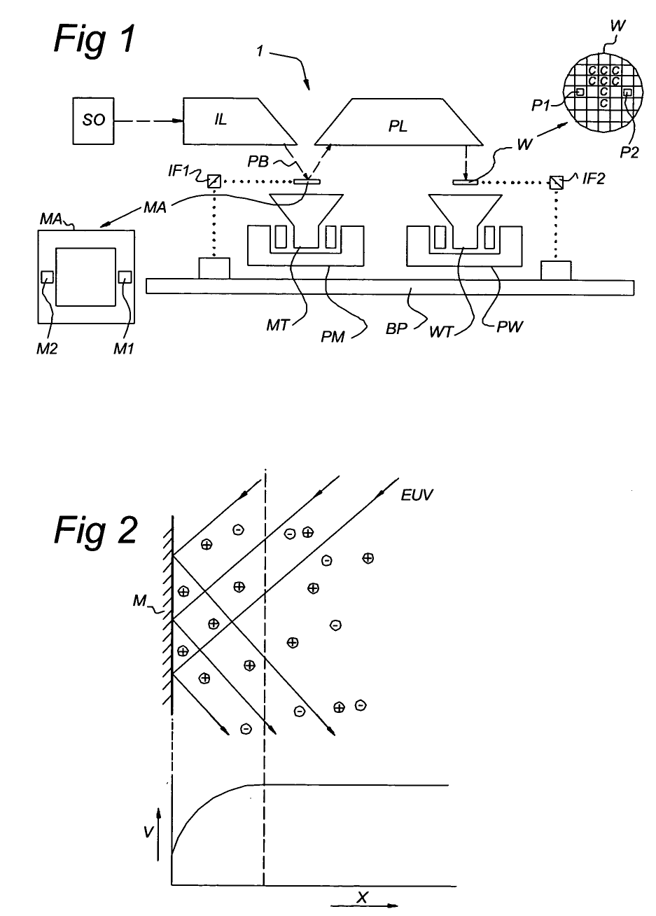

FIG. 1 schematically depicts a lithographic apparatus according to a particular embodiment of the invention. The apparatus includes: an illumination system (illuminator) IL for providing a projection beam PB of radiation (e.g. UV or EUV radiation); a first support structure (e.g. a mask table) MT for supporting patterning device (e.g. a mask) MA and connected to first positioning device PM for accurately positioning the patterning device with respect to item PL; a substrate table (e.g. a wafer table) WT for holding a substrate (e.g. a resist-coated wafer) W and connected to second positioning device PW for accurately positioning the substrate with respect to item PL; and a projection system (e.g. a reflective projection lens) PL for imaging a pattern imparted to the projection beam PB by patterning device MA onto a target portion C (e.g. including one or more dies) of the substrate W. The term “table” as used herein can also be considered or termed as a “support.” It should be understood that the term support or table broadly refers to a structure that supports, holds, or carries a patterning device, mask, or substrate.

As here depicted, the apparatus is of a reflective type (e.g. employing a reflective mask or a programmable mirror array of a type as referred to above). Alternatively, the apparatus may be of a transmissive type (e.g. employing a transmissive mask).

The illuminator IL receives a beam of radiation from a radiation source SO. The source and the lithographic apparatus may be separate entities, for example when the source is a plasma discharge source. In such cases, the source is not considered to form part of the lithographic apparatus and the radiation beam is generally passed from the source SO to the illuminator IL with the aid of a radiation collector including, for example, suitable collecting mirrors and/or a spectral purity filter. In other cases, the source may be integral part of the apparatus, for example when the source is a mercury lamp. The source SO and the illuminator IL, may be referred to as a radiation system.

The illuminator IL may include an adjusting device for adjusting the angular intensity distribution of the beam. Generally, at least the outer and/or inner radial extent (commonly referred to as σ-outer and σ-inner, respectively) of the intensity distribution in a pupil plane of the illuminator may be adjusted. The illuminator provides a conditioned beam of radiation, referred to as the projection beam PB, having a desired uniformity and intensity distribution in its cross-section.

The projection beam PB is incident on the mask MA, which is held on the mask table MT. Being reflected by the mask MA, the projection beam PB passes through the lens PL, which focuses the beam onto a target portion C of the substrate W. With the aid of the second positioning device PW and position sensor IF2 (e.g. an interferometric device), the substrate table WT may be moved accurately, e.g. so as to position different target portions C in the path of the beam PB. Similarly, the first positioning device PM and position sensor IF1 may be used to accurately position the mask MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner), the mask table MT may be connected to a short stroke actuator only, or may be fixed. Mask MA and substrate W may be aligned using mask alignment marks M1, M2 and substrate alignment marks P1, P2.

The depicted apparatus can be used in the following preferred modes:

1. In step mode, the mask table MT and the substrate table WT are kept essentially stationary, while an entire pattern imparted to the projection beam is projected onto a target portion C in one go (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the projection beam is projected onto a target portion C (i.e. a single dynamic exposure). The velocity and direction of the substrate table WT relative to the mask table MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the projection beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

As already discussed above, in case EUV radiation is used, mirrors M are used to project the projection beam PB. In that case it is observed that a plasma is formed in front of the mirrors M as a result of the EUV-radiation in low pressure Argon or other gasses present in the chamber containing one or more mirrors M of the lithographic projection apparatus 1. The existence of this plasma has experimentally been confirmed as a glow in the collected EUV bundle.

The plasma includes electrons and positive ions. When these particles collide with the surface of one of the mirrors M, these particles are absorbed. However, because the electrons travel faster than the positive ions, an electric field is generated over a distance that corresponds with the Debije length, as will be understood by a person skilled in the art. FIG. 2 schematically shows the distribution of electrons and positive ions in the vicinity of the mirror M. The lower part of FIG. 2 schematically shows the potential V as a function of the distance x from the mirror M.

It can be seen in FIG. 2 that an electric field exists in the vicinity of the mirror M, directed perpendicular to the surface of the mirror M. This electric field accelerates the positive ions towards the surface of the mirror M. When these ions hit the surface of the mirror M, the surface of the mirror M is damaged, i.e. the ions etch the surface of the mirror M. This has a negative effect on the reflectivity of the mirror M.

In EP 1 186 957, a dynamic protective layer was presented. The thickness of the protective layer was controlled by two competitive processes at the surface of the mirror. The first was the growth of the protective layer due to CₓH_{y} contamination, regulated by controlling the pressure of a hydrocarbon gas. The second process is the etching of the surface of the mirror by fast incoming ions coming from the source. The thickness of the protective layer is controlled by adjusting the pressure of the hydrocarbon gas.

According to the present invention, a gas pressure is maintained for providing a protective layer due to CₓH_{y} contamination, by controlling the plasma induced etching.

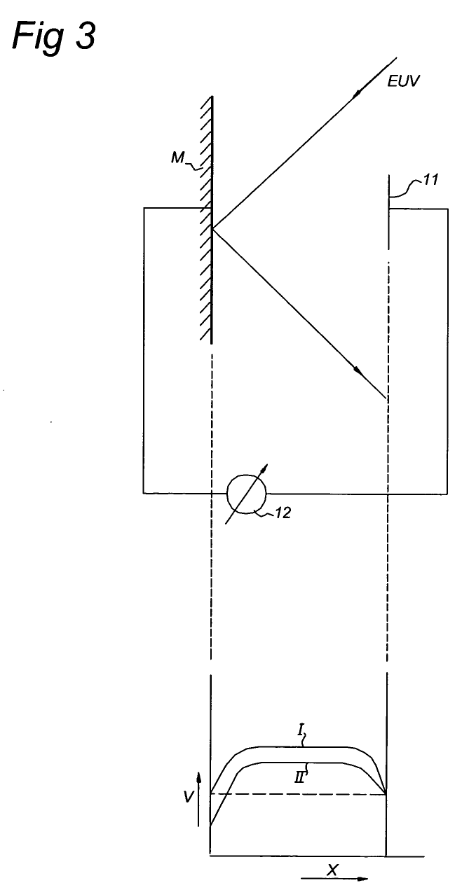

FIG. 3 shows an example of a mirror M according to an embodiment of the invention. The figure shows an electrode 11 facing the surface of the mirror M. The mirror M and the electrode 11 are both connected to an adjustable voltage source 12. In the lower part of FIG. 3 the potential V is depicted as a function of the distance from the surface of the mirror M towards the electrode. The curve indicated by I shows the potential V in case the adjustable voltage source 12 is set to zero. If, however, the adjustable voltage source 12 is set to a value different from zero, the potential V in the vicinity of the mirror M is altered. For example, if a negative voltage is applied to the mirror M relative to the electrode 11, the electric field E will look like the curve in the lower part of FIG. 3 indicated by II, showing a higher potential difference between the mirror M and the center of the plasma. It will be understood that in that case, the positive ions will be accelerated to a higher velocity and the etching of the mirror M will increase. Of course, the etching may also be decreased by applying a positive voltage to the surface of the mirror M with respect to the electrode 11.

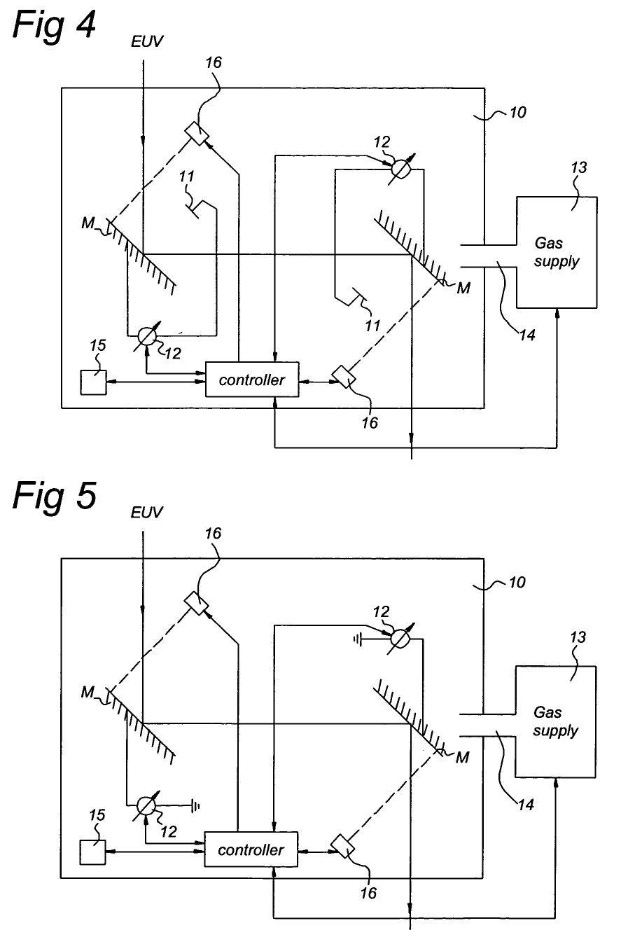

FIG. 4 shows a chamber 10 that includes two mirrors M that are both connected to an adjustable voltage source 12 according to FIG. 3. FIG. 4 shows only two mirrors, but of course any other suitable number of mirrors M may be used. If the mirrors M are used to project a patterned beam PB to a substrate W, usually 6 mirrors are used. Further on, the mirrors M may be provided with actuators (not shown) to control their orientation.

FIG. 4 further shows an inlet 14 connected to a gas supply 13. The gas supply 13 provides the chamber 10 with, for example, a hydrocarbon gas. Hydrocarbon molecules may adsorb to the surface of the mirror M, thereby forming a protective layer on the surface of the mirror M, as already discussed above. The amount of gas in the chamber 10 determines the speed of the growth of the protective layer. In order to ensure a constant growth of the protective layer, a sensor 15 is provided in the chamber 10 that measures the amount of hydrocarbon in the chamber. If the amount of hydrocarbon is kept constant, a constant growth may be assumed. The sensor is connected to a controller 17 that is also connected to gas supply 13. The controller 17 controls the amount of hydrocarbon in chamber 10 via gas supply 13 based on a sensor signal from sensor 15.

At the same time, the protective layer is gradually eroded as a result of plasma induced etching. If this erosion of the protective layer is in equilibrium with the growth of the protective layer, a constant thickness of the protective layer may be established. Because the protective layer reduces the reflectivity of the mirror M, the thickness of the protective layer may be measured by measuring the reflectivity of the mirror M. The reflectivity may, for example, be measured by measuring the light intensity of incoming and reflected light of a certain mirror M, and determining the ratio between these two measured values. Many types of sensors for measuring reflectivity are known to a person skilled in the art. FIG. 4 shows such a reflectivity sensor 16 for each of the mirrors M in schematic form. The dotted line towards the mirror M indicates a beam for measuring reflectivity. The sensors 16 are connected to a controller 17 that is also connected to the adjustable voltage sources 12. Based on the measured reflectivity by the sensors 16, each adjustable voltage source 12 may be separately controlled by the controller 17 to provide the mirror M with a desired voltage V, in order to increase or decrease the amount of etching. If the determined reflectivity is in accordance with a desired reflectivity, the setting of the adjustable voltage source 12 should not be altered by the controller 17.

The protective layer may be kept at a certain thickness that provides sufficient protection of the mirror M, while not reducing the reflectivity of the mirror too much.

Before use, the mirror M may already be provided with an initial protective layer. In use, the thickness of the protective layer may be maintained by the mechanism described above.

The electrode 11 may have all kind of shapes. For example, the electrode 11 may be a plate having a similar shape and dimensions as the mirror M. Alternatively, the electrode 11 may be a ring-shaped wire, a straight wire, or a point source, or may have any other suitable shape.

Many different hydrocarbon (HₓC_{y}) gasses are suitable for use in this invention. Examples of suitable gasses include, but are not limited to acetic anhydride, n-amyl alcohol, amyl benzoate, diethylene glycol ethyl ether, acrylic acid, adipic acid, and 2-tert-butyl-4-ethylphenol.

It will be understood that the etching rate of the protective layer is not only determined by the voltage difference between the plasma and the mirror surface, but may also be determined by the characteristics of the hydrocarbon molecules used. For example, bigger ions may etch the protective layer or the mirror M more effectively.

FIG. 5 depicts a further embodiment of the invention. The same reference numbers are used for similar objects shown in FIG. 4. In this embodiment, the adjustable voltage source 12 is at one side connected to the mirror M, and is grounded on the other side. No electrodes 11 are provided. It will be understood that, in general, applying a negative voltage to the mirrors M is sufficient to control plasma induced etching. Of course, it is also possible to apply a positive voltage to the surroundings, such as the surrounding walls.

It is understood that the voltage applied to the mirrors M should not be used to simply cancel the voltage difference that occurs at the borders of the plasma. This is due to the fact that the processes that occur are non-stationary and strongly time dependent, as will be understood by a person skilled in the art.

According to a further embodiment of the invention, one or more electrodes 11 may be formed as a mesh (not shown). Using a mesh may help creates a well-defined voltage drop between the mirror M and the electrode 11.

While specific embodiments of the invention have been described above, it will be appreciated that the invention may be practiced otherwise than as described. The description is not intended to limit the invention.

1. A method of supplying a dynamic protective layer to a mirror in a lithographic apparatus to protect the mirror from etching by ions, the method comprising:
supplying a gaseous matter to a chamber containing the mirror;
monitoring reflectivity of the mirror; and
controlling the thickness of the protective layer by controlling a potential of a surface of the mirror based on the monitored reflectivity of the mirror.

2. A method according to claim 1, wherein the gaseous matter comprises a gaseous hydrocarbon (HₓC_{y}).

3. A method according to claim 2, wherein the gaseous hydrocarbon is selected from a group consisting of: acetic anhydride, n-amyl alcohol, amyl benzoate, diethylene glycol ethyl ether, acrylic acid, adipic acid, and 2-tert-butyl-4-ethylphenol.

4. A method according to claim 1, wherein the mirror is used to image a mask to a substrate.

5. A method according to claim 1, wherein the mirror is used to project an EUV radiation beam.

6. A method according to claim 1, further comprising monitoring a background pressure in said chamber.

7. A device manufacturing method comprising:
patterning a beam of radiation received from a radiation system;
projecting the patterned beam of radiation onto a target portion of a layer of radiation-sensitive material on a substrate; and
supplying a dynamic protective layer to a mirror in the radiation system to protect the mirror from etching by ions, wherein said supplying a dynamic protective layer comprises
(i) supplying a gaseous matter to a chamber containing the mirror;
(ii) monitoring reflectivity of the mirror; and
(iii) controlling the thickness of the protective layer by controlling a potential of a surface of the mirror based on the monitored reflectivity of the mirror.

8. A method according to claim 7, wherein the gaseous matter comprises a gaseous hydrocarbon (HₓC_{y}).

9. A method according to claim 8, wherein the gaseous hydrocarbon is selected from a group consisting of: acetic anhydride, n-amyl alcohol, amyl benzoate, diethylene glycol ethyl ether, acrylic acid, adipic acid, and 2-tert-butyl-4-ethylphenol.

10. A method according to claim 7, wherein said supplying a dynamic protective layer further comprises monitoring a background pressure in said chamber.

11. A device manufacturing method comprising:
patterning a beam of radiation;
projecting the patterned beam of radiation with a projection system onto a target portion of a layer of radiation-sensitive material on a substrate; and
supplying a dynamic protective layer to a mirror in the projection system to protect the mirror from etching by ions, wherein said supplying a dynamic protective layer comprises
(i) supplying a gaseous matter to a chamber containing the mirror;
(ii) monitoring reflectivity of the mirror; and
(iii) controlling the thickness of the protective layer by controlling a potential of a surface of the mirror based on the monitored reflectivity of the mirror.

12. A method according to claim 11, wherein the gaseous matter comprises a gaseous hydrocarbon (HₓC_{y}).

13. A method according to claim 12, wherein the gaseous hydrocarbon is selected from a group consisting of: acetic anhydride, n-arnyl alcohol, arnyl benzoate, diethylene glycol ethyl ether, acrylic acid, adipic acid, and 2-tert-butyl-4-ethylphenol.

14. A method according to claim 11, wherein said supplying a dynamic protective layer further comprises monitoring a background pressure in said chamber.

15. An apparatus for supplying a dynamic protective layer to a mirror to protect the mirror from etching by ions, the apparatus comprising:
a chamber containing the mirror;
an inlet for supplying a gaseous matter to the chamber;
a monitor for monitoring reflectivity of the mirror; and
a controllable voltage source for applying a potential to a surface of the mirror in order to control the thickness of the protective layer in dependence on said reflectivity of said mirror.

16. An apparatus according to claim 15, wherein the gaseous matter comprises a gaseous hydrocarbon (HₓC_{y}).

17. An apparatus according to claim 16, wherein the gaseous hydrocarbon is selected from a group consisting of: acetic anhydride, n-amyl alcohol, amyl benzoate, diethylene glycol ethyl ether, acrylic acid, adipic acid, and 2-tert-butyl-4-ethylphenol.

18. An apparatus according to claim 15, wherein the controllable voltage source is at one end connected to the mirror and at another end connected to an electrode facing the mirror.

19. An apparatus according to claim 15, wherein the controllable voltage source is at one end connected to the mirror and at another end connected to ground.

20. An apparatus according to claim 15, further comprising a second monitor for monitoring a background pressure in the chamber.

21. A lithographic projection apparatus comprising:
a radiation system for providing a beam of radiation;
a support structure for supporting a patterning device, the patterning device serving to pattern the beam of radiation according to a desired pattern;
a substrate table for holding a substrate;
a projection system for projecting the patterned beam onto a target portion of the substrate; and
a mirror protection device for supplying a dynamic protective layer to a mirror in the radiation system to protect the mirror from etching by ions, the mirror protection device comprising:
(i) a chamber containing the mirror;
(ii) an inlet for supplying a gaseous matter to the chamber;
(iii) a monitor for monitoring reflectivity of the mirror; and
(iv) a controllable voltage source for applying a potential to a surface of the mirror in order to control the thickness of the protective layer in dependence on said reflectivity of said mirror.

22. An apparatus according to claim 21, wherein the gaseous matter comprises a gaseous hydrocarbon (HₓC_{y}).

23. An apparatus according to claim 22, wherein the gaseous hydrocarbon is selected from a group consisting of: acetic anhydride, n-amyl alcohol, amyl benzoate, diethylene glycol ethyl ether, acrylic acid, adipic acid, and 2-tert-butyl-4-ethylphenol.

24. A lithographic projection apparatus comprising:
a radiation system for providing a beam of radiation;
a support structure for supporting a patterning device, the patterning device serving to pattern the beam of radiation according to a desired pattern;
a substrate table for holding a substrate;
a projection system for projecting the patterned beam onto a target portion of the substrate; and
a mirror protection device for supplying a dynamic protective layer to a mirror in the projection system to protect the mirror from etching by ions, the mirror protection device comprising:
(i) a chamber containing the mirror;
(ii) an inlet for supplying a gaseous matter to the chamber;
(iii) a monitor for monitoring reflectivity of the mirror; and
(iv) a controllable voltage source for applying a potential to a surface of the mirror in order to control the thickness of the protective layer in dependence on said reflectivity of said mirror.

25. An apparatus according to claim 24, wherein the gaseous matter comprises a gaseous hydrocarbon (HₓC_{y}).

26. An apparatus according to claim 25, wherein the gaseous hydrocarbon is selected from a group consisting of: acetic anhydride, n-amyl alcohol, amyl benzoate, diethylene glycol ethyl ether, acrylic acid, adipic acid, and 2-tert-butyl-4-ethylphenol.
